(19) United States
(12) Patent Application Publication
(10) Pub. No.: US 2009/0230557 A1
(43) Pub. Date: Sep. 17, 2009

(54) Semiconductor Device and Method for Making Same

(75) Inventors: Stefan Eckert, Dresden (DE); Thomas Leonhardt, Freiberg (DE); Joerg Pantfoerder, Dresden (DE); Lutz Quas, Dresden (DE)

Correspondence Address: INFINEON TECHNOLOGIES AG;Patent Department, MUC 11.1.507, P.O. Box 221644, Munich, 80506, DE

(73) Assignee: INFINEON TECHNOLOGIES AG, Neubiberg (DE)

(21) Appl. No.: 12/049,405

(22) Filed: Mar. 17, 2008

(51) Int. Cl. H01L 23/48; H01L 21/768

(52) U.S. Cl. 257/773; 438/637; 257/E23.011; 257/E21.577

(57) ABSTRACT

One or more embodiments are related to a semiconductor device, comprising: a metallic layer having a top surface and a sidewall surface; an intermediate layer disposed on a sidewall surface of the metallic layer; a dielectric layer disposed over the metallic layer, the dielectric layer having an opening formed therethrough; and a conductive material disposed within the opening, the conductive material at least partially overlying the top surface of the metallic layer, the conductive material being electrically coupled to the metallic layer.

### FIELD OF THE INVENTION

Generally, the present invention relates to semiconductor devices and methods of making semiconductor devices. More particularly, the present invention relates to via processing in metallization technology.

### BACKGROUND OF THE INVENTION

In semiconductor manufacturing, conductive interconnects are frequently formed. Such interconnects may, for example, be used to electrically couple lines of one metallization level to lines of another metallization level.

### BRIEF DESCRIPTION OF THE DRAWINGS

FIGS. 1 through 6 show an embodiment of a method of making an opening in accordance with the present invention; and

FIG. 7 shows an embodiment of an opening in accordance with the present invention.

### DETAILED DESCRIPTION OF THE INVENTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

In one or more embodiments, a metallic aluminum or aluminum alloy metallization system may include a stack of layers. As an example, the stack of layers may include a layer of titanium, a layer of metallic aluminum or of an aluminum alloy (such as an aluminum copper alloy) overlying the layer of titanium and an etch stop layer of TiN (titanium nitride) overlying the layer of metallic aluminum or aluminum alloy. It is noted that via processing in a metallic aluminum or aluminum alloy metallization system may require a high selectivity oxide to TiN etch to ensure that the TiN serves as a reliable etch stop layer. The selectivity of the via etch may be limited by the tools, chemicals and etch process used. An increase in the thickness of the TiN stop layer may be limited by the mask used for the etch process of the metallic aluminum or aluminum alloy line (which may, for example, be a resist mask or a hard mask) and by disadvantageous effects of thermo mechanical stress in the metallic aluminum or aluminum alloy (for example, increase of the compressive stress in metallic aluminum or aluminum alloy or extrusions of metallic aluminum or aluminum alloy).

When forming an opening through an oxide interlayer dielectric, it is possible that a sidewall surface of the metallic aluminum line may be damaged by the via etch and following process steps. This may result in the formation of a non-reliable via. This may also result in the degradation of the electromigration lifetime.

As an example, it is possible that one or more of the following events occur: formation of aluminum fluoride along the sidewalls of the metallic aluminum lines, formation of micro voids in the metallic aluminum during the nucleation of the WF₆, and/or the formation of interfaces containing carbon residuals.

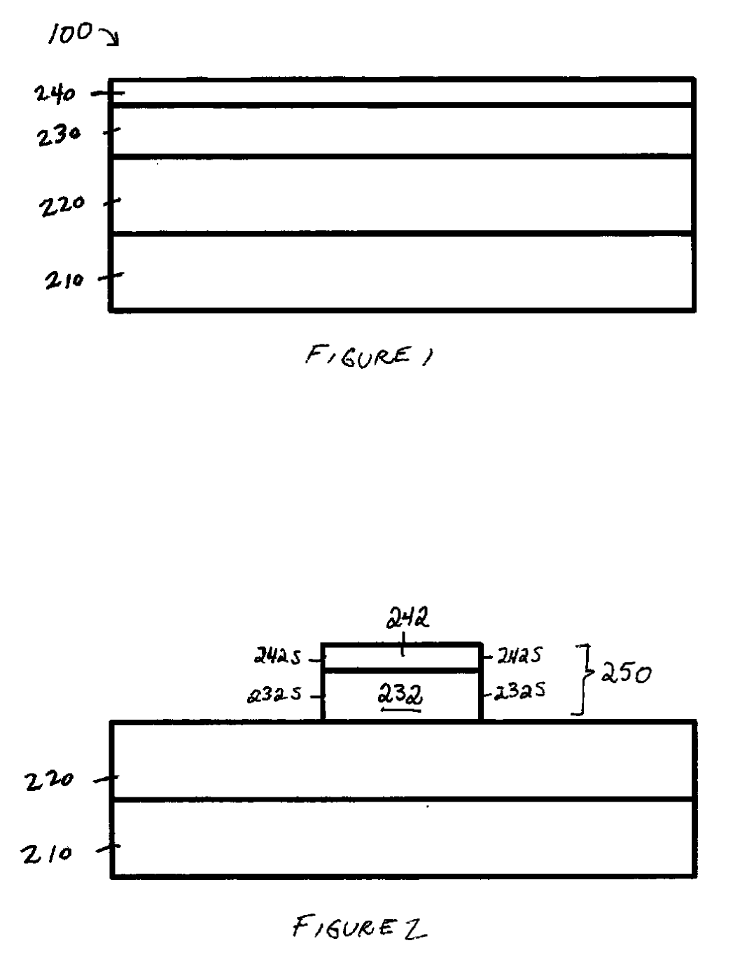

FIGS. 1 through 6 provide an embodiment of a method of making a via opening in accordance with the present invention. FIG. 1 shows a semiconductor structure 100 of an embodiment of a partially completed semiconductor chip or device. The structure 100 comprises a substrate 210. In one or more embodiments of the invention, the substrate 210 may be a p-type substrate. However, more generally, in one or more embodiments of the invention, the substrate 210 may be a silicon substrate or other suitable substrate. The substrate 210 may be a silicon-on-insulator (SOI) substrate. The SOI substrate may, for example, be formed by a SIMOX process. The substrate may be a silicon-on-sapphire (SOS) substrate. The substrate may be a silicon-on-germanium substrate.

Formed over the substrate 210 is an optional layer 220. The layer 220 may itself include one or more levels of metallization layers (for example, Metal-1, Metal-2, Metal-3, etc), inter-level dielectric layers, conductive interconnects such as conductive vias and plugs, barrier layers etc. In one or more embodiments, at least a top portion of the layer 220 may comprise an inter-level dielectric layer having conductive vias. The combination of the layer 210 and layer 220 may be viewed as a workpiece or a support structure for the deposition of additional layers over such a workpiece or support structure.

Referring to FIG. 1, a metal layer 230 may be formed over the layer 220. The metal layer 230 may be formed of any metallic material. In one or more embodiments, the metallic material may include one or more of the elements Al, Cu, Au, Ag, W, and Ti. The metallic material may be a pure metal or a metal alloy. In one or more embodiments, it is possible that a pure metal may include trace amounts of impurities. The metallic material may be a metal alloy. The metal alloy may comprise two or more metallic elements. The metal alloy may consist essentially of two or more metallic elements. The metal alloy may comprise a metallic element and a non-metallic element. In one or more embodiments, the metal alloy may, for example, be steel. The metal alloy may comprise the element carbon. Examples of pure metals include, but are not limited to, pure copper, pure gold, pure silver, pure aluminum, pure tungsten, and pure titanium. Examples of metals include metallic copper, metallic gold, metallic silver, metallic aluminum, metallic tungsten, and metallic titanium. Examples of metal alloys include, but are not limited to, copper alloys, gold alloys, silver alloys, aluminum alloys, tungsten alloys, and titanium alloys. An example of a metal alloy is a copper aluminum alloy. The metal layer 220 may be part of a metallization level (such as Metal-1, Metal-2, etc).

Generally, the thickness of the metal layer 230 is not limited to any particular thickness. In one or more embodiments, the metal layer 230 may have a thickness of about 2000 nm or less. In one or more embodiments, the metal layer 230 may have a thickness of about 1000 nm (1000 nanometers) or less. In one or more embodiments, the metal layer 230 may have a thickness of about 500 nm or less. In one or more embodiments, the metal layer 230 may have a thickness of about 250 nm or less. In one or more embodiments, the metal layer 230 may have a thickness of about 200 nm or less. In one or more embodiments, the metal layer 230 may have a thickness of about 150 nm or less. In one or more embodiments, the metal layer 230 may have a thickness of about 150 nm or more. In one or more embodiments, the metal layer 230 may have a thickness of about 200 nm or more.

Referring to FIG. 1, a stop layer 240 may be formed over the metal layer 230. The stop layer 240 may comprise a conductive material. The stop layer 240 may comprise a ceramic material. The stop layer 240 may be comprise a compound. The stop layer 240 may comprise an intermetallic compound. The stop layer 230 may comprise a metallic material. The metallic material may be a pure metal or a metal alloy. The metal alloy may include one or more non-metallic elements. The stop layer 230 may comprise one or more of the elements from the group consisting of the elements Ti, Ta, Al, N and W. In one or more embodiments, the stop layer 230 may include (a) the element N and (b) one or more of the elements selected from the group consisting of Ti, Ta, Al and W. In one or more embodiments, it is possible that the stop layer comprise a dielectric material.

The stop layer 230 may comprise a Ti-based material or a Ta-based material. The stop layer 240 may comprise one or more materials selected from the group consisting of TiW, WN, TiN, and TaN. In one or more embodiment, the stop layer 240 may comprise TiN. In one or more embodiments, the stop layer 240 may comprise TaN. The stop layer 240 may be formed as a composite or as a dual-layered system such as a Ti/TiN or a Ta/TaN dual-layer. The stop layer 240 may serve to lower or prevent diffusion between the materials that are on opposite sides of the stop layer. The stop layer 240 may be deposited by a chemical vapor deposition (CVD) or a physical vapor deposition (PVD) process.

The thickness of the stop layer 240 is not limited to any particular thickness. In one or more embodiments, the thickness of the stop layer may be about 100 nm or less. In one or more embodiments, the thickness of the stop layer may be about 75 nm or less. In one or more embodiments, the thickness of the stop layer may be about 60 nm or less. In one or more embodiments, the thickness of the etch stop layer may be about 10 nm or more. In one or more embodiments, the thickness of the stop layer may be about 20 nm or more. In one or more embodiments, the thickness of the stop layer may be about 30 nm or more. In one example, the thickness of the stop layer may be about 50 nm.

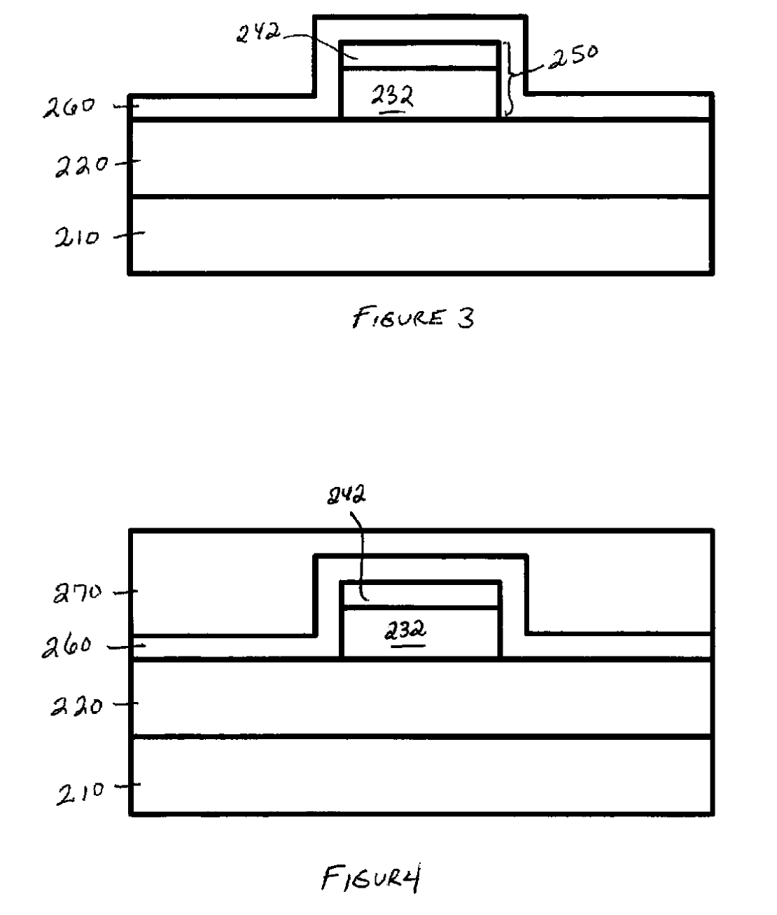

The metal layer 230 and the stop layer 240 that are shown in FIG. 1 may then be masked and etched. The etching process removes a portion of the stop layer 240 as well as a portion of the metal layer 230 so as to form the structure shown in FIG. 2 (after the mask has been removed) illustrating a remaining portion 232 of the metal layer 230 as well as a remaining portion 242 of the stop layer 240. It is noted that the same etch may also possibly remove a portion of the layer 220.

Referring to FIG. 2, the remaining portion 232 of the metal layer 230 and the remaining portion 242 of the stop layer 240 forms a metal line stack 250. In one or more embodiments, there may be two or more metal line stacks. In an embodiment, each of the metal line stacks may be spacedly disposed from each other. In an embodiment, each of the metal line stacks may be electrically isolated from each other. The metal line stack 250 comprises the metal line 232 and a remaining portion 242 of the stop layer 240 (from FIG. 1).

The metal line 232 may be a metal line which is part of a metallization layer of a semiconductor device. For example, a semiconductor device may have a plurality of metallization layers where each metallization layer corresponds to a metallization level such as Metal-1, Metal-2, Metal-3, etc. Metal lines from one metallization layer may be electrically coupled to metal lines in another metallization layer (either above or below) with the use of conductive interconnects such as conductive vias or conductive plugs. For example, one or more metal lines from the metallization layer Metal-1 may be electrically coupled to the metallization layer Metal-2 through one or more conductive interconnects such as conductive vias. One or more metal lines in the in the metallization layer of the lowest metallization may be electrically coupled to one or more conductive portions of the substrate through the use of conductive interconnects such as conductive vias or conductive plugs.

Referring to FIG. 2, it is seen that after the formation of the metal line stack 250, the stop layer portion 242 has sidewall surfaces 242S. Likewise, the metal line 232 has sidewall surfaces 232S. In one or more embodiments, a stop layer may have one or more sidewall surfaces. In one or more embodiments, a metal line may have one or more sidewall surfaces.

After the etch of the metal layer 230 and stop layer 240 (shown FIG. 1) to form the metal line stack 250 (shown in FIG. 2), the structure may then be subjected to an optional anneal process so as to apply heat to the metal line 232.

Referring to FIG. 3, after the optional anneal process, an intermediate layer 260 may then be deposited over the metal line stack 250. The deposition may be a substantially conformal deposition wherein the intermediate layer 260 is deposited over the top surface of the metal line stack 250 as well as the sidewall surfaces of the metal line stack 250. In the embodiment shown in FIG. 3, the intermediate layer 260 is formed over the top surface and sidewall surfaces of the remaining stop layer portion 242 as well as over the sidewall surfaces of the metal layer 232. The intermediate layer 260 may also be formed over the top surface of the layer 220.

In one or more embodiments, the intermediate layer 260 may be a dielectric material. In one or more embodiments, the intermediate layer may comprise an oxide. The oxide may be silicon oxide. In one or more embodiments, the intermediate layer may comprise a nitride. The nitride may be an insulative nitride. The nitride may be a silicon nitride (such as Si₃N₄). In one or more embodiments, the intermediate layer may comprise an oxynitride. The oxynitride may be a silicon oxynitride (such as SiON). In one or more embodiments, the intermediate layer may comprise one or more of the elements selected from the group consisting of Si, O, and N. In one or more embodiments, the intermediate layer may comprise a dielectric material. In one or more embodiments, the intermediate layer may comprise a conductive material. In one or more embodiments, the intermediate layer 260 may comprise a metallic material. In one or more embodiments, the intermediate layer 260 may comprise a ceramic material.

The thickness of the intermediate layer is not limited to any particular value. In one or more embodiments, the intermediate layer may have a thickness of about 100 nm or less. In one or more embodiments, the intermediate layer may have a thickness of about 75 nm or less. In one or more embodiments, the intermediate layer may have a thickness of about 50 nm or less. In one or more embodiments, the intermediate layer 260 may have a thickness of about 40 nm or less. In one or more embodiments, the intermediate layer may have a thickness of about 5 nm or more. In one or more embodiments, the intermediate layer may have a thickness of about 10 nm or more. In one or more embodiments, the intermediate layer may have a thickness of about 20 nm or more. As an example, the intermediate layer may have a thickness of about 30 nm.

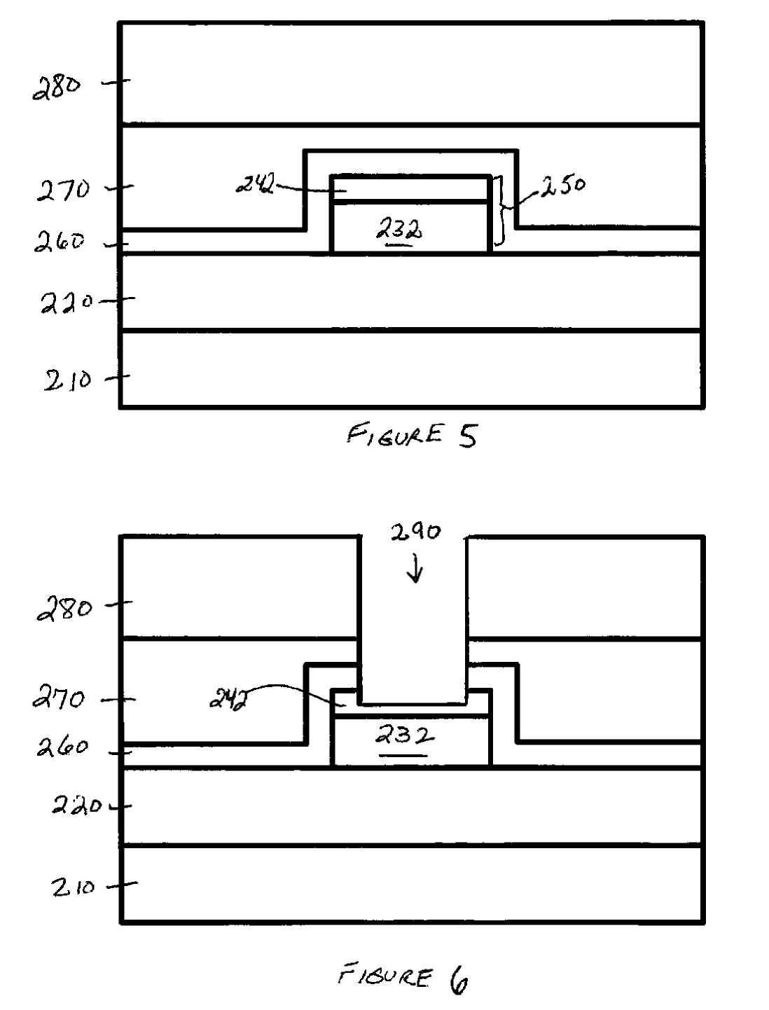

Referring to FIG. 4, after the formation of the intermediate layer 260, a first dielectric layer 270 may be deposited over the intermediate layer 260. Referring to FIG. 5, a second dielectric layer 280 may then be formed over the first dielectric layer 270. It is noted that the second dielectric layer 280 is optional, and, in another embodiment of the invention, the process may be performed without the second dielectric layer 280. In one or more embodiments, the first dielectric layer 270 and the second dielectric layer 280 may serve as inter-level dielectric layers between different levels of metallization (for example, between Metal-1 and Metal-2, between Metal-2 and Metal-3, etc.). In one or more embodiments, the first dielectric layer 270 and the second dielectric layer 280 may also serve a dielectric layers between the substrate and the first (or lower) metallization level Metal-1 of a semiconductor device.

The first and second dielectric layers may comprise any dielectric material. The dielectric material may be an oxide (such as SiO₂). The dielectric material may a nitride. The dielectric material may be an oxynitride. In one or more embodiments, the second dielectric layer may be formed of the same dielectric material as the first dielectric material. In one or more embodiments, the second dielectric layer may be formed of a different dielectric material as the first dielectric layer. In one or more embodiments, the first dielectric layer 270 may substantially lack the element N (the element nitrogen). In one or more embodiments, the second dielectric layer 280 may substantially lack the element N (the element nitrogen).

As noted above, the intermediate layer 260 may be formed of a dielectric material. In one or more embodiments, the dielectric material of the intermediate layer 260 may be different from the dielectric material of the first dielectric layer 270. In one or more embodiments, the dielectric material of the intermediate layer 260 may be the same as the dielectric material of the dielectric layer 270. In one or more embodiments, the dielectric material of the intermediate layer 260 may be different from the dielectric material of the second dielectric layer 280. In one or more embodiments, the dielectric material of the intermediate layer 260 may be the same as the dielectric material of the second dielectric layer 280.

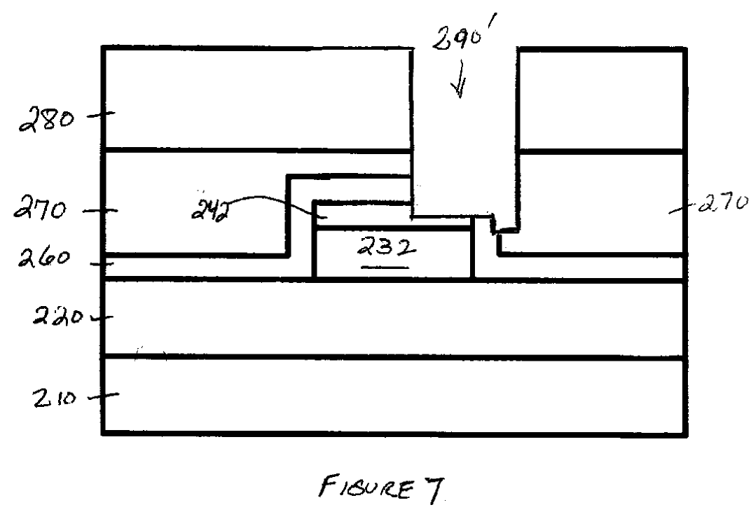

Referring to FIG. 6, an opening 290 may then be formed through the second dielectric layer 280, through the first dielectric layer 270 and through the intermediate layer 260 so as to expose the stop layer 242. In the embodiment shown, the opening 290 is made so that it stops within the stop layer 242. In another embodiment, it may be made to stop on top of the stop layer 260 such that the stop layer 242 is exposed. In the embodiment shown in FIG. 6, the opening 290 does not expose the metal line 232 (that is, the opening 290 does not reach the metal line 232). The opening 290 may be formed by an etch process. One or more etch chemistries may be used to form the opening 290. On one or more embodiments the etch used to form the opening 290 may be a wet etch. In one or more embodiments, an example of a possible etchant may be C₅ F₈. In one or more embodiments, other compounds including the elements carbon and fluorine may be used.

In another embodiment, it is conceivable that the opening 290 may be formed so as to go through the stop layer 242 and to expose the metal line 232. In one or more embodiments, the opening 290 may be formed as a hole. In one or more embodiments, the opening 290 may be formed as a via opening. The via opening may be a hole. In one or more embodiments, the opening 290 may be formed as a trench.

The opening 290 may be used as an opening for a conductive interconnect such as a conductive via or conductive plug. In one or more embodiments, the conductive via may be a non landing via.

In one or more embodiments, an optional barrier layer may be deposited along the sidewall and bottom surfaces of the opening 290. A conductive material may then be deposited within the opening to serve as a conductive interconnect for a semiconductor device. The conductive interconnect may, for example, be a conductive via or a conductive plug. The conductive material may, for example, comprise a metallic material. The conductive material may comprise one or more of the elements Al, Cu, Au, Ag, W, Ti and Ta. The metallic material may, for example, be a pure metal or a metal alloy. The pure metal may, for example, be pure aluminum, pure copper, purge gold, pure silver, pure tungsten or pure titanium. The metallic material may be an alloy such as aluminum alloy, copper alloy, gold alloy, silver alloy, tungsten alloy or titanium alloy. The conductive material may serve as a conductive interconnect electrically coupling a first metallization layer to a second metallization layer which is either above or below the first metallization layer. The conductive interconnect may be a conductive via or conductive plug. The conductive material may serve as a conductive interconnect between a metallization layer and a conductive portion of the substrate.

It is noted that an etching selectivity S is given by the ratio of the etching rate ER for an “a”-material and for a “b”-material as follows:

S_{(a:b)}=ERₐ/ER_{b}

wherein the selectivity may be indicated as a ratio or as a number and the etching rate ER indicates the layer thickness Δd etched per unit time ΔT. So that:

ER=Δd/ΔT

In one or more embodiment, for the etch used to form the opening 290 through the first dielectric layer 270, the etch rate of the first dielectric layer 270 may be greater than the etch rate of the stop layer 242. In one or more embodiments, the selectivity of the first dielectric layer 270 relative to the stop layer 242 may be at least 5 to 1. Hence, in one or more embodiments, the ratio of the etch rate of the first dielectric layer 270 to the etch rate of the stop layer 242 may be at least 5 to 1. In one or more embodiments, for the etch used to form the opening 290 through the first dielectric layer 270, the selectivity of the first dielectric layer 270 relative to the stop layer 242 may be at least 10 to 1. Hence, in one or more embodiments, the ratio of the etch rate of the first dielectric layer 270 to the etch rate of the stop layer 242 may be at least 10 to 1. In one or more embodiments, for the etch used to form the opening 290 through the first dielectric layer 270, the selectivity of the first dielectric layer 270 relative to the stop layer 242 may be at least 15 to 1. Hence, in one or more embodiments, the ratio of the etch rate of the first dielectric layer 270 to the etch rate of the stop layer 242 may be at least 15 to 1. In one or more embodiments, for the etch used to form the opening 290 through the first dielectric layer, the selectivity of the first dielectric layer 270 relative to the stop layer 242 may be at least 20 to 1. Hence, in one or more embodiments, the ratio of the etch rate of the first dielectric layer 270 to the etch rate of the stop layer 242 may be at least 20 to 1. In one or more embodiments, for the etch used to form the opening 290 through the first dielectric layer, the selectivity of the first dielectric layer 270 relative to the stop layer 242 may be at least 25 to 1. Hence, in one or more embodiments, the ratio of the etch rate of the first dielectric layer 270 to the etch rate of the stop layer 242 may be at least 25 to 1.

In one or more embodiments, for the etch used to form the opening 290 through the first dielectric layer 270, the etch rate of the first dielectric layer 270 may be greater than the etch rate of the intermediate layer 260. In one or more embodiments, for the etch used to form the opening 290 through the first dielectric layer 270, the selectivity of the first dielectric layer 270 relative to the intermediate layer 260 may be at least 5 to 1. Hence, in one or more embodiments, the ratio of the etch rate of the first dielectric layer 270 to the etch rate of the intermediate layer 260 may be at least 5 to 1. In one or more embodiments, for the etch used to form the opening 290 through the first dielectric layer 270, the selectivity of the first dielectric layer 270 relative to the intermediate layer 260 may be at least 10 to 1. Hence, in one or more embodiments, the ratio of the etch rate of the first dielectric layer 270 to the etch rate of the intermediate layer 260 may be at least 10 to 1. In one or more embodiments, for the etch used to form the opening 290 through the first dielectric layer 270, the selectivity of the first dielectric layer 270 relative to the intermediate layer 260 may be at least 15 to 1. Hence, in one or more embodiments, the ratio of the etch rate of the first dielectric layer 270 to the etch rate of the intermediate layer 260 may be at least 15 to 1. In one or more embodiments, for the etch used to form the opening 290 through the first dielectric layer 270, the selectivity of the first dielectric layer 270 relative to the intermediate layer 260 may be at least 20 to 1. Hence, in one or more embodiments, the ratio of the etch rate of the first dielectric layer 270 to the etch rate of the intermediate layer 260 may be at least 20 to 1. In one or more embodiments, for the etch used to form the opening 290 through the first dielectric layer 270, the selectivity of the first dielectric layer 270 relative to the intermediate layer 260 may be at least 25 to 1. Hence, in one or more embodiments, the ratio of the etch rate of the first dielectric layer 270 to the etch rate of the intermediate layer 260 may be at least 25 to 1.

In one or more embodiments, for the etch used to form the opening 290 through the first dielectric layer 270, the selectivity of the intermediate layer 260 relative to the stop layer 242 may be about 1 to 1. In one or more embodiments, for the etch used to form the opening 290 through the first dielectric layer 270, the etch rate of the intermediate layer 260 may be about the same as the etch rate of the stop layer 242. In one or more embodiments, it is possible that the intermediate layer 260 may be used as an additional stop layer for the etch of the opening 290 through the first dielectric layer 270.

Adjustments of the etch depth into the stop layer 242 and a reliable etch stop within the stop layer material may be achieved by using this additional intermediate layer 260. The intermediate layer 260 may also serve to protect the sidewall surfaces 232S of the metal line 232. In the embodiment shown in FIG. 6, the opening 290 is shown such that all of the opening 290 overlies the top surface of metal line 232. However, it is also possible that a portion of the opening 290 is formed which does not overlie the top surface of the metal line 232. This is shown in FIG. 7, wherein a portion of the opening 292 does not overlie the top surface of the metal line 232.

In cases such a the one shown in FIG. 7, the intermediate layer 260 that lines the sidewall surfaces of the metal line 232 may help to protect the metal line 232 when the opening 292 is formed as well as during subsequent processing. In particular, the intermediate layer 260 may help to protect the sidewall surface 232S of the metal line 232.

The intermediate layer 260 may help to protect the sidewall surface 232S from attack from chemicals or materials which may used to form the opening 292. The intermediate layer may, for example, help to reduce the formation of a metal fluoride (such as aluminum fluoride) on the sidewall surfaces 232S of the metal line 232. The intermediate layer 260 may also help to reduce the formation of micro voids in the metal line 232 that, for example, may result during nucleation of WF₆ (it is possible that micro voids may, for example, be caused by attack of the WF₆).

Referring again to FIGS. 5 and 6, in another embodiment of the invention, it is possible that the first dielectric layer 270 be used without the second dielectric layer 280. Hence, in this embodiment, the opening 290 may be formed without the use of the second dielectric layer 280.

Referring to FIG. 6, in another embodiment of the invention, it is possible that the stop layer 242 be eliminated. In this embodiment, the intermediate layer 260 is disposed over or on (and in contact with) a top surface of the metal line 232. In this embodiment, the intermediate layer 242 would also be disposed over or on (and in contact with) the sidewall surfaces 232S of the metal line 232. In this embodiment, the intermediate layer 260 may still provide protection to the sidewall surfaces 232S of the metal line 232 during the etch to form opening 290. In one or more embodiments (when the stop layer 242 is not used), the opening 290 may expose the intermediate layer 260 but not the metal line. In one or more embodiments, the opening 290 may expose the metal line.

Referring to FIG. 5, in another embodiment of the invention, it is possible that the intermediate layer be appropriately etched so that it is removed from the top surface of the layer 220 before the formation of the opening 290. In yet another embodiment of the invention, it is possible that the intermediate layer be appropriately etched so that it is removed from top surface of the stop layer 242 as well as from the top surface of the layer 220 before the formation of the opening 290. In yet another embodiment of the invention, it is possible that the intermediate layer be appropriately etched so that it is removed from the top surface of the layer 220 before the formation of the opening 290.

An embodiment of the present invention may be a semiconductor device, comprising: a metallic layer having a top surface and a sidewall surface; an intermediate layer disposed over a sidewall surface of the metallic layer; a dielectric layer disposed over the metallic layer, the dielectric layer having an opening formed therethrough; and a conductive material disposed within the opening, the conductive material at least partially overlying the top surface of the metallic layer, the conductive material being electrically coupled to the metallic layer.

An embodiment of the present invention may be a semiconductor device, comprising: a first metallization level comprising at least one first metal line; a second metallization level comprising at least one second metal line, the second metallization level being above the first metallization level; a conductive interconnect electrically coupling the second metal line to the first metal line; and a material disposed on a sidewall surface of the first metal line, the material comprises a silicon nitride or a silicon oxynitride.

An embodiment of the present invention may be a method for making a semiconductor device, comprising: forming a metallic layer, the metallic layer having a top surface and a sidewall surface; forming an etch stop layer over the top surface of the metallic layer; forming an intermediate layer over the sidewall surface of the metallic layer; forming a dielectric layer over the top surface of the metallic layer and over the intermediate layer; and etching the dielectric layer, the etch rate of the dielectric layer being greater than the etch rate of the intermediate layer.

An embodiment of the present invention may be a method of forming a semiconductor device, comprising: forming a metal layer; forming a stop layer over the metal layer; forming an intermediate layer over the stop layer and over a sidewall surface of the metal layer; forming a dielectric layer over the intermediate layer; and forming an opening through the dielectric layer and through the intermediate layer, the opening at least partially overlying the metal layer.

It is to be understood that the disclosure set forth herein is presented in the form of detailed embodiments described for the purpose of making a full and complete disclosure of the present invention, and that such details are not to be interpreted as limiting the true scope of this invention as set forth and defined in the appended claims.

What is claimed is:

1. A semiconductor device, comprising:
a metallic layer having a top surface and a sidewall surface;
an intermediate layer disposed over a sidewall surface of said metallic layer;
a dielectric layer disposed over said metallic layer, said dielectric layer having an opening formed therethrough; and
a conductive material disposed within said opening, said conductive material at least partially overlying the top surface of said metallic layer, said conductive material being electrically coupled to said metallic layer.

2. The device of claim 1, wherein said intermediate layer comprises a dielectric material, said intermediate layer being formed of a different material than said dielectric layer.

3. The device of claim 1, wherein said intermediate layer comprises an insulative nitride or an oxynitride.

4. The device of claim 1, wherein said intermediate layer comprises silicon nitride or silicon oxynitride.

5. The device of claim 1, further comprising a stop layer disposed between the top surface of said metallic layer and said dielectric layer, said stop layer comprising a conductive material.

6. The device of claim 5, wherein said stop layer comprises a conductive nitride.

7. The device of claim 5, wherein said stop layer comprises TiN, TaN or WN.

8. The device of claim 1, wherein said intermediate layer is additionally disposed between the top surface of said metallic layer and said dielectric material.

9. The device of claim 8, further comprising a stop layer between the top surface of said metallic layer and said intermediate layer.

10. The device of claim 9, wherein said stop layer comprises a conductive nitride.

11. The device of claim 1, wherein said metallic layer comprises pure aluminum or an aluminum alloy.

12. A semiconductor device, comprising:
a first metallization level comprising at least one first metal line;
a second metallization level comprising at least one second metal line, said second metallization level being above said first metallization level;
a conductive interconnect electrically coupling said second metal line to said first metal line; and
a material disposed on a sidewall surface of said first metal line, said material comprises a silicon nitride or a silicon oxynitride.

13. The device of claim 12, wherein said at least one first metal line and said at least one second metal line comprises pure aluminum or an aluminum alloy.

14. A method for making a semiconductor device, comprising:
forming a metallic layer, said metallic layer having a top surface and a sidewall surface;
forming an etch stop layer over the top surface of said metallic layer;
forming an intermediate layer over the sidewall surface of said metallic layer;
forming a dielectric layer over the top surface of said metallic layer and over said intermediate layer; and
etching said dielectric layer, the etch rate of said dielectric layer being greater than the etch rate of said intermediate layer.

15. The method of claim 14, wherein said intermediate layer is additionally formed over the top surface of said etch stop layer.

16. The method of claim 14, wherein said etching step includes etching said intermediate layer.

17. The method of claim 15, wherein said etching step forms an opening in said dielectric layer and said intermediate layer, said opening at least partially overlying said metallic layer.

18. The method of claim 14, further comprising etching said stop layer, the etch rate of said dielectric layer being greater than the etch rate of said stop layer.

19. The method of claim 14, wherein said metallic layer comprises the element Al.

20. The method of claim 14, wherein said stop layer comprises a conductive nitride.

21. A method of forming a semiconductor device, comprising:
forming a metal layer;
forming a stop layer over said metal layer;
forming an intermediate layer over said stop layer and over a sidewall surface of said metal layer;
forming a dielectric layer over said intermediate layer; and
forming an opening through said dielectric layer and through said intermediate layer, said opening at least partially overlying said metal layer.

22. The method of claim 21, wherein said intermediate layer is formed by a substantially conformal deposition.

23. The method of claim 21, wherein said metal layer comprises metallic aluminum or an aluminum alloy.

24. The method of claim 21, wherein said stop layer comprises a conductive nitride.

25. The method of claim 21, wherein said intermediate layer comprises an insulative nitride or an insulative oxynitride.
